(19) United States
(12) Patent Application Publication
(10) Pub. No.: US 2001/0046817 A1
(43) Pub. Date: Nov. 29, 2001

(54) Compliant pin and its method of manufacture

(76) Inventor: Edward E. Putnam, Murieta, CA (US)

Correspondence Address: KNOBBE MARTENS OLSON & BEAR LLP, 620 NEWPORT CENTER DRIVE, SIXTEENTH FLOOR, NEWPORT BEACH, CA, 92660, US

(21) Appl. No.: 09/780,247

(22) Filed: Feb. 9, 2001

Related U.S. Application Data
(60) Provisional application No. 60/181,308, filed on Feb. 9, 2000.

(51) Int. Cl. H05K 1/00

(52) U.S. Cl. 439/751

(57) ABSTRACT

A compliant pin, for insertion into an aperture within a printed circuit board (PCB) or connector housing, which includes a longitudinal body having a first end and a second end and a compliant portion located between the first and second ends, wherein the compliant portion includes deformable elements formed integrally and seamlessly with the longitudinal body and further defining a cavity there between, each of the deformable elements deforming into the cavity when the pin is inserted into the aperture. Circuit board and connector assemblies utilizing a plurality of the aforementioned pins are also disclosed. The invention further includes embodiments of a method of manufacturing a compliant pin wherein, in one embodiment, at least one compliant portion having a cavity is formed into a wire, comprising the steps of coining the wire in at least one place such that a cavity having walls is created; and thereafter forming the walls of the cavity into a desired shape and configuration. The second embodiment of a method of manufacturing at least one compliant pin comprises the steps of blanking out a plurality of sections on a sheet of metal such that the remaining portions define wires of a desired length, width, and shape; followed by coining the wires in at least one place such that a cavity having walls is created; and thereafter forming the walls of said cavity into a desired shape and configuration.

### RELATED APPLICATIONS

The present application claims priority to copending provisional application having the same title, application Ser. No. 60/181,308, filed Feb. 9, 2000, which is hereby incorporated by reference.

### FIELD OF THE INVENTION

The invention relates to contact pins which are used to provide mechanical and/or electrical connections between various bodies or structures. More particularly, the invention relates to improvements to compliant pins to provide enhanced strength and securing force with respect to their use in members such as printed circuit boards (PCBs), connector housings, and header housings.

### BACKGROUND OF THE INVENTION

Electrical contacts, otherwise referred to as terminals or contact pins, are used in the electronics industry in conjunction with printed circuit boards (PCB's), electrical panels, connector cables and other devices, for making electrical connections. As used herein, the terms “electrical” and “electronic”, and conjugations thereof, are synonymous and interchangeable, and refer to any component, circuit, device or system which utilizes the principles of electricity in its operation.

A plurality of the contact pins are frequently mounted in an insulative male connector housing, with one end of the contacts extending from the connector housing so as to make mechanical and electrical contact with a female mating connector. In a typical high pin count (HPC) header, for example, which is a commercially available male connector, contacts or wire pins which normally have a circular or square cross-section are staked into round holes in a housing. Retention of the pins in the housing is achieved by a press fit, otherwise known as “negative clearance,” between the contact pins and the holes of the connector housing. The contact pins are typically made from bronze, brass, steel, stainless steel or copper alloy and the connector housing is typically made from a plastic or resin type material. During the staking process, the holes of the connector housing can become enlarged and deformed due to the negative clearance between the pin and the perimeter of the holes. This degrades the ability of the connector housing to securely hold the contact pins in their proper position and alignment. As used herein, the terms “connector”, “header”, “housing”, and any combination and/or conjugation thereof, are synonymous and interchangeable, and refer to any body, panel, board, device or structure having secured contact pins therein for providing electrical and/or mechanical connections.

One improvement in the past has been to provide recesses and fins, otherwise known as “stars,” on the longitudinal side surface of contact pins to form a retention portion on the contact pins. These star retention portions provide extra holding power when the contact pin is inserted into a connector housing. The recesses and their corresponding fins are formed by stamping technology in which the fins are forced or extruded outwardly as the recesses or grooves are stamped into the retention portion of the contact pin.

Typically, contact pins are formed from square or round wire, or strip metal, made from either steel, stainless steel, bronze, brass or copper alloy. The star feature is a section of the pin that has been expanded by striking the square section, or diameter, of the wire or strip with chisel-like tools on four sides at the same time. This action causes four “V” shaped depressions to be produced in the wire. Between the depressions, a fin is raised above the original diameter or in the case of a square wire, above the diagonal dimension of the wire. Therefore, the star feature is an enlarged portion of the contact pin and is used to provide increased press fit between the contact pin and a hole of a connector housing.

Even with the utilization of these star retention features, however, the connector industry is plagued by defective connectors due to inadequate retention of the contact pins in their connector housings. Many problems occur in connectors due to loose contact pins. These pins may fall out or move partially out of their intended position causing mechanical and/or electrical failure. Past solutions that have been proposed to solve this problem have included increasing the amount of press fit, or negative clearance, between the holes of a connector housing and the contact pins. This is accomplished by making the star feature larger or the hole smaller. However, this approach has not been effective because it has caused cracking or warpage of the connector housing. Similarly, contact headers on PC boards, or the PC boards themselves, have been known to break or crack if a pin, or the star feature of a pin, is too large.

Another proposed solution has been a connector pin utilizing a manufacturing method whereby pin is flattened and folded in such a way so as to produce a compliant portion having a cavity. Unfortunately, the manufacturing process, aside from being lengthy, also produced seams at the points where the folds were made, resulting in weaker connector pins.

Accordingly, a need in the industry exists for a connector pin which can be securely retained within a connector housing, without causing damage to the connector housing. Furthermore, a need exists for a method of producing such a pin that is efficient and produces pins that are not weakened by the presence of seams.

### SUMMARY OF THE INVENTION

In a first aspect of the invention, an improved compliant pin is disclosed. In one exemplary embodiment, the compliant pin comprises a substantially longitudinal body element having a first and second end; and a compliant portion disposed in proximity to at least one of the first and second ends, the complaint portion having first and second distal elements, these first and second distal elements defining walls of a cavity so as to be deformed upon insertion of the compliant portion within an aperture such as that formed in a printed circuit board (PCB). Furthermore, this improved compliant pin is formed by a method of manufacture which results in a seamless transition between its body and its compliant portion, allowing for increased strength over other compliant pins which have been produced in the past.

In a second aspect of the invention, a circuit board assembly incorporating the aforementioned compliant pin is disclosed. In one exemplary embodiment, the circuit board assembly comprises a circuit board substrate, a compliant pin having at least one compliant portion; at least one electrically conductive circuit trace disposed on the substrate; and at least one aperture adapted to receive the at least one compliant portion, the at least one aperture formed within the substrate and contacting at least a portion of the circuit trace, thereby allowing electrical current to flow between the compliant pin and the circuit trace.

In a third aspect of the invention, a connector assembly incorporating the aforementioned compliant pin is disclosed. In one exemplary embodiment, the connector assembly comprises a filtered header connector and at least one compliant pin having either one or two compliant portions. One of the compliant portions is used to provide a compliant electrical connection with filter media within the connector, while the second (optional) compliant portion can be used to provide a press-fit electrical connection with an external component such as a printed circuit board (PCB).

Finally, a method of manufacturing a compliant pin is disclosed whereby at least one compliant portion having a cavity is formed into a wire, comprising the steps of coining the wire in at least one place such that a cavity having walls is created; and thereafter forming the walls of the cavity into a desired shape and configuration. The coining process may be performed by lying the wire into a groove of a die, and pressing down over a portion of the said wire with a tool punch. Subsequently, the forming of the walls may be performed by pressing down over said walls with a separate die to deform them inwardly so as to create a more rounded cross section to the cavity.

A second embodiment of a method of manufacturing a series of compliant pins having at least one compliant portion comprises the steps of blanking out a plurality of sections on a sheet of metal such that the remaining portions define wires of a desired length, width, and shape; followed by coining the wires in at least one place such that a cavity having walls is created; and thereafter forming the walls of said cavity into a desired shape and configuration. As in the first embodiment of a manufacturing method, these last two steps of coining and forming may be performed using the same devices discussed in the previous paragraph.

### BRIEF DESCRIPTION OF THE DRAWINGS

FIG. 1 is a perspective view of the compliant pin in relationship to a printed circuit board having an aperture.

FIG. 2 is a detailed perspective view of the compliant pin of FIG. 1.

FIG. 3 is a top plan view of the compliant pin of FIG. 1.

FIG. 4 is a cross-sectional view of the compliant pin, taken along lines 4-4 of FIG. 3

FIG. 5 is a cross-sectional view of the compliant portion of the pin, taken along lines 5-5 of FIG. 3.

FIG. 6 is a side plan view of the compliant pin of FIG. 1.

FIG. 7 is a plan view of a portion of a pin carrier showing two pins held therein.

FIG. 8 is a perspective view of a single pin retention element within the pin carrier of FIG. 7.

FIG. 9 is a perspective view of a selected portion of a component assembly comprising a printed circuit board and the compliant pin of FIG. 1.

FIG. 10 is a perspective view of an exemplary connector assembly comprising a connector housing, electrical filter media, and plurality of compliant pins.

FIG. 11 is a cross-sectional view of a coining system, illustrating the process of coining a pin in accordance with the invention.

FIG. 12 is a cross-sectional view of a coining system, illustrating the process of coining a pin in accordance with the invention.

FIG. 13 is a cross-sectional view of a forming system, illustrating the process of final sizing a pin in accordance with the invention.

FIG. 14 is a cross-sectional view of a forming system, illustrating the process of final sizing a pin in accordance with the invention.

FIG. 15 is a top plan view of a ‘blanked out’ metal sheet and resulting wires after use of a blanking process to form the wires from the metal sheet.

FIG. 16 is a top view of the compliant portion of a pin produced by a ‘wire’ manufacturing method, showing the grain of the wire running longitudinally to the main axis of the pin.

FIG. 17 is a top view of the compliant portion of a pin produced by a ‘strip’ manufacturing method, showing the grain of the wire running transverse to the main axis of the pin.

### DETAILED DESCRIPTION OF THE INVENTION

Reference is now made to the drawings wherein like numerals refer to like parts throughout.

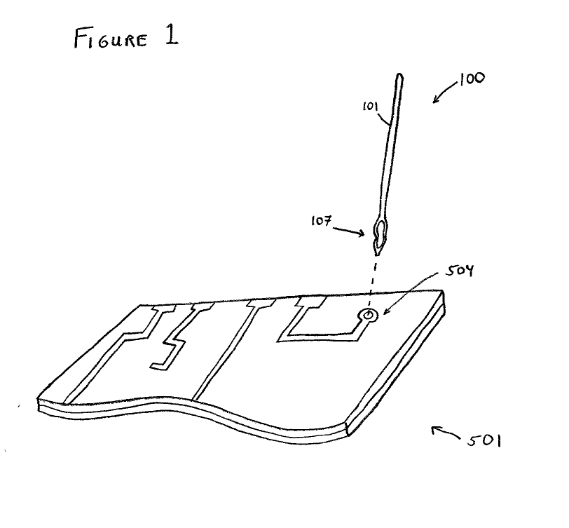

Referring now to FIG. 1, one exemplary embodiment of the compliant pin 100 of the invention is shown in its preferred application. The compliant pin comprising a longitudinal body 101 and a compliant portion 107 is shown in relationship to a printed circuit board (PCB) 501 having an aperture 504. The compliant portion 107 of the pin 100 is designed so as to fit into the aperture 504 in a manner so as to allow maximum retention of the pin.

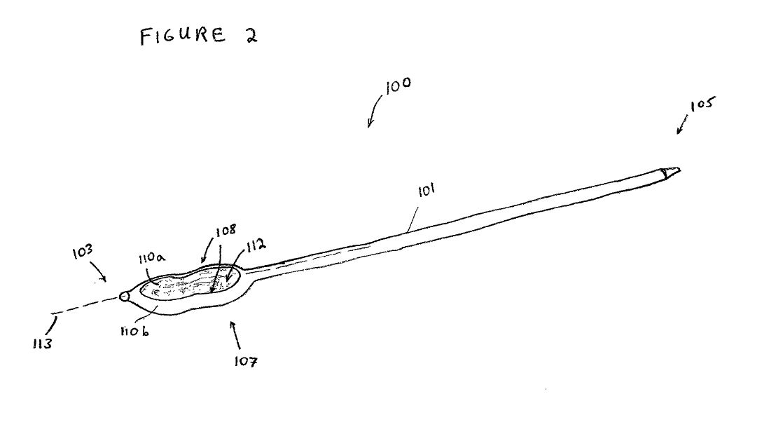

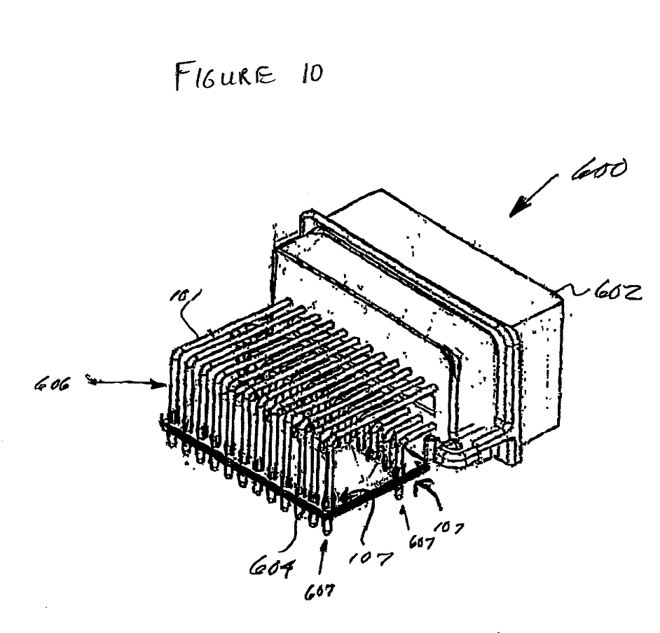

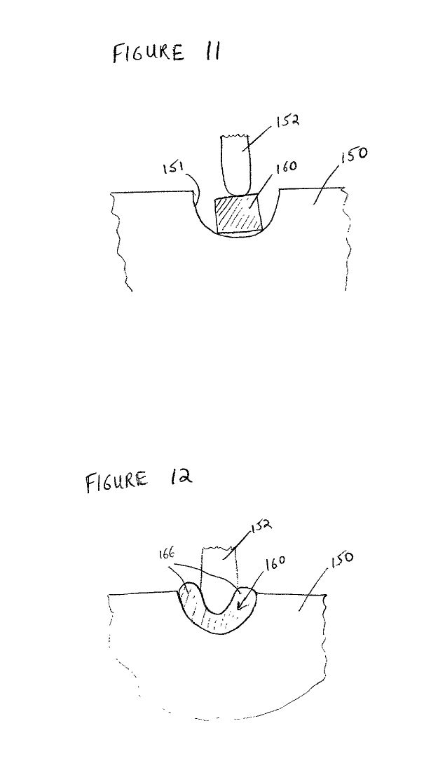

The compliant pin 100 of FIG. 1 may be described in more detail with reference to FIG. 2. The compliant pin 100 comprises generally a longitudinal body 101 having a first end 103 and a second end 105. Between the first and second ends 103, 105, and disposed in substantial proximity to the first end 103 is a compliant portion 107 for, inter alia, holding the compliant pin 100 in an aperture 504 of a printed circuit board 502, or a connector housing 602, both of which will be described more fully with respect to FIGS. 9 and 10, respectfully.

Still referring to FIG. 2, it is seen that the body 101 is generally of elongated shape, having a longitudinal axis 113. It can be seen that the compliant portion 107 of the illustrated embodiment includes two distal, deformable elements 108 each having inner and outer surfaces 110a and 110b, respectfully, which define a cavity 112 formed generally within the longitudinal body of the pin 100.

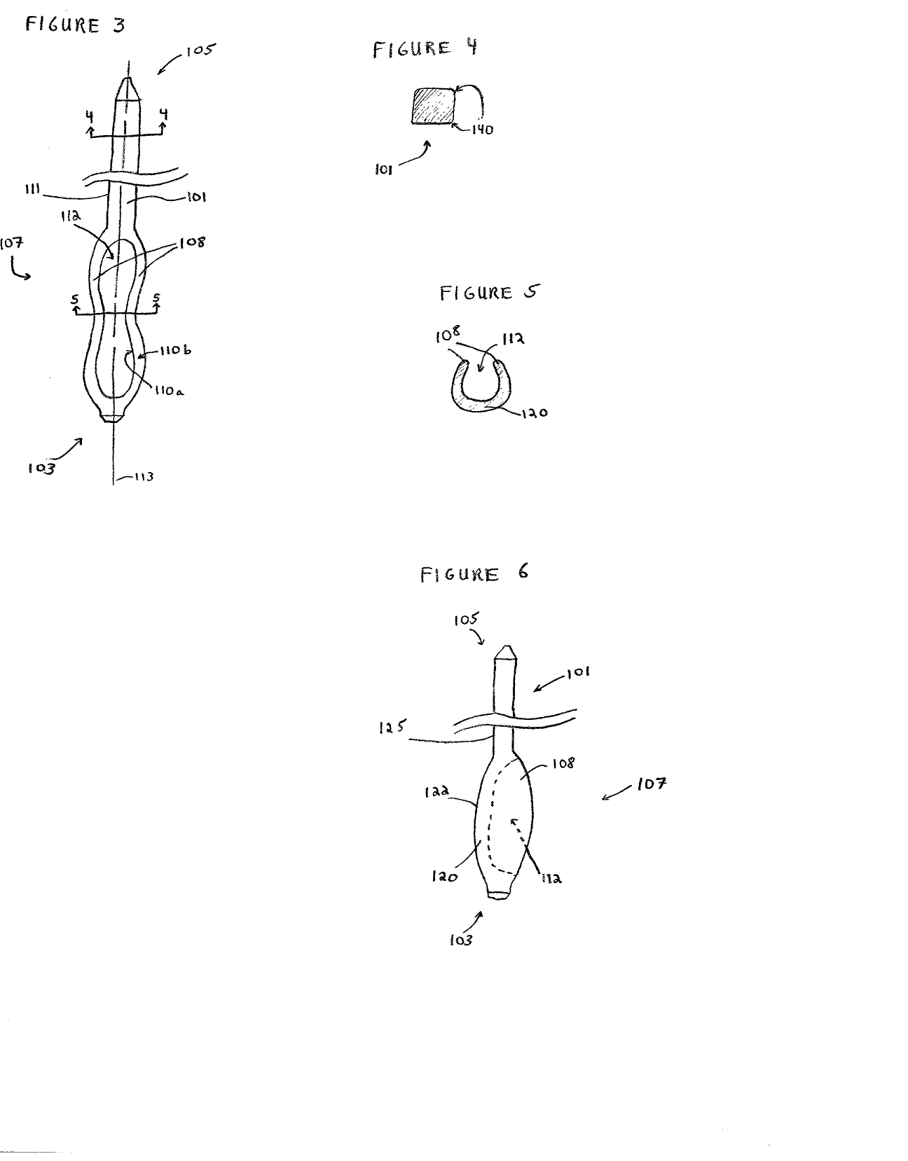

Examining the pin more closely with reference to FIG. 3, each deformable element 108 is generally oriented parallel to the longitudinal axis 113 of the pin 100, and extends or “bulges” somewhat beyond the plane of the side and top surfaces 111 of the body 101. The deformable elements 108 of the illustrated embodiment also have a somewhat variable thickness and a generally “S” shaped (or “Figure 8” shaped when viewed collectively) appearance when viewed from above, as illustrated in FIG. 3. The ends 103 and 105 of the pin 100 are optionally tapered as shown in FIG. 3, so as to facilitate insertion of the pin 100 into an aperture.

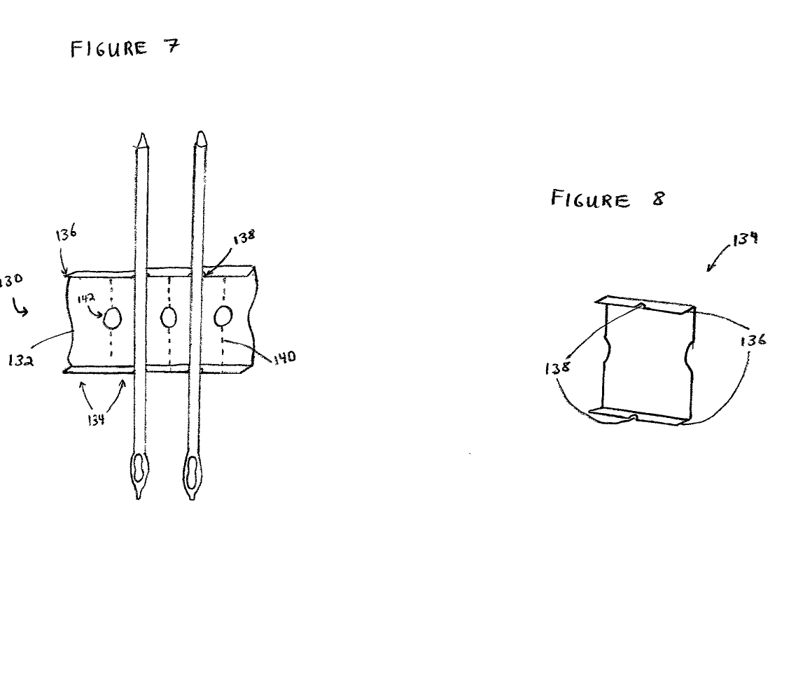

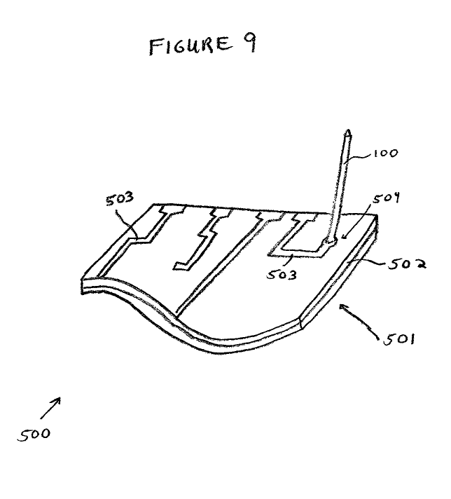

In FIG. 4, the cross-sectional view taken along lines 4-4 of the longitudinal body 101 of the pin of FIG. 3 shows that body as having a generally square shape with somewhat rounded edges 140. It will be recognized, however, that other cross-sectional shapes and configurations may be used for the body 101 of the pin including, for example, a circular cross-section of constant diameter, tapering diameter, rectangular cross-section, elliptical cross-section, hexagonal cross-section, etc.

FIG. 5 shows the cross-section of the compliant portion 107 taken along lines 5-5 of FIG. 3, illustrating the deformable elements 108, cavity 112, and bottom wall element 120.

As illustrated in FIG. 6, a body portion 120 of the compliant portion 107 is oriented generally parallel to the longitudinal axis 113. The outer surface 122 of the body portion 120 is shaped such that it also protrudes or “bulges” somewhat with respect to the corresponding surface 125 of the body 101 of the pin 100. The foregoing “bulge” feature increases the amount of surface area that comes in contact with the material of the PCB (or other component) thereby assisting in “grabbing” the material of the PCB in the press fit area, and increasing the frictional force between the components.

Hence, the body portion 120, deformable elements 108, and compliant pin body 101 cooperate to define the cavity 112 formed generally within the compliant portion 107, with the compliant portion 107 generally forming a raised or enlarged section with respect to the rest of the body 101 of the pin 100.

It is noted that while the deformable elements 108, body portion 120, pin body 101, and cavity 112 have been illustrated with specific geometric shapes, modifications to these shapes are considered to be within the scope of the invention described herein. For example, the individual deformable elements 108 may be “flat” (planar), “U” or “V” shaped in horizontal cross-section versus “S” shaped as previously described. Furthermore, the disposition of the compliant portion 107 with respect to the pin body 101 may be altered; i.e., the compliant portion may be altered in relative length, width, or overall profile, and/or translated in longitudinal position along the axis 113 of the pin. For example, the compliant portion 107 could be a greater fraction of the overall length of the pin 100, have “V” shaped deformable elements 108, and be positioned at a point not in substantial proximity to either end 103, 105 of the pin 100. The compliant portion 107 may also be rotated with respect to the surfaces 111, 125 around the longitudinal axis 113 if desired. Alternatively, the pin 100 could include multiple compliant portions 107 disposed at two or more locations on the pin body 101. Many such permutations are possible, all being within the scope of the invention.

In terms of material of construction, the compliant pin 100 of the invention is formed, in one embodiment, from a readily available metal or alloy such as bronze, brass, steel, stainless steel, copper alloy, although it will be appreciated that other material having desirable mechanical and electrical properties may conceivably be used. The compliant pin 100 may be formed using any number of conventional metal forming techniques, such techniques being known to those of ordinary skill in the art. It should be noted however, that in the preferred embodiments of the method of manufacture, which will be discussed in following paragraphs, the compliant portion 107 is formed to be seamless, resulting in increased strength over other types of compliant pins which are manufactured differently.

In reference now to FIG. 7, a compliant pin carrier 130 of the invention is described. In the illustrated embodiment, the carrier comprises a substantially planar carrier element 132 having a series of pin retention elements 134 formed adjacent to one another. The pin retention elements 134 of the illustrated embodiment generally comprise pairs of upturned elements 136 which are formed generally by bending the upper and lower sides of the carrier element 132 at approximately a ninety degree angle to the plane of carrier element.

These upturned elements 136 and their orientation to the rest of the element are more clearly illustrated in FIG. 8, which shows one single pin retention element in isolation. Each upturned element 136 has a receiving notch or aperture 138 formed therein in such size and alignment that a compliant pin 100 will be retained frictionally therein. The retention elements 134 are disposed substantially in parallel along the carrier element 132 such that several compliant pins 100 can be retained on the carrier one along side the other, as shown in FIG. 7 (which only shows two pins). Holes 142 are cut into the carrier in between pin retention elements 134, to function as guiding holes that could fit over protrusions on a track, such as those used in automated production lines. Furthermore, grooves 140, as shown in FIG. 7, are cut into the carrier 132 between the retention elements 134 such that the carrier element 132 can be deformed from its normal planar geometry, thereby permitting longer carrier elements containing many compliant pins to be “rolled” onto a circular drum or storage roller.

Referring now to FIG. 9, one application of the above-described compliant pin is illustrated, comprising an assembly 500 in which the pin 100 is connected to a printed circuit board (PCB) 501 having an upper layer or substrate 502. A compliant pin 100 is functionally fitted within an aperture 504 formed within the substrate 502, forming an electrical connection between the pin 100 and a circuit trace 503 extending from the aperture 504. While the illustrated embodiment of the assembly 500 establishes an electrical conduction path, it will be recognized that such conduction path need not exist (i.e., the compliant pin may merely be used for mechanical support if desired). Furthermore, other assemblies utilizing one or more compliant pins 100, such as electrical connector housings, are also contemplated by the present invention.

As the pin 100 is inserted for operation into the aperture 504 within the PCB 501 or other component, the compliant portion 107 will tend to expand the aperture. However, the “memory” or resilience of the material of the PCB substrate 502, which defines the perimeter of the hole, will cause portions of the substrate that are not forced outwardly by the compliant portion 107 to partially deform around the compliant portion 107. Similarly, the deformable elements 108 of the compliant portion 107 will deform somewhat and be moved inward toward the cavity area during pin insertion to allow even further insertion thereof and securing of the pin 100 to the substrate 502. The deformable elements 108 also have some “memory” such that when the aperture expands (such as during a temperature change of the substrate material), the compliant portion 107 with deformable elements 108 will maintain a secure interference fit with the aperture.

Referring now to FIG. 10, another exemplary embodiment of a connector assembly is disclosed, incorporating at least one of the compliant pins previously described. As illustrated in FIG. 10, the assembly 600 comprises a connector housing 602 having a first connection to a series of connector pins 606 travelling therefrom to a second connection within a capacitive filter media 604. In the illustrated embodiment, the compliant pins 606 each include one compliant portion 107 similar to that of the pin 100 of FIG. 2 herein, disposed substantially at the distal end 607 of each pin 606. The compliant portion 107 of each pin 606 is used to provide a press-fit compliant electrical connection with the terminals of the filter media 604 disposed adjacent to the connector housing 602. In the illustrated embodiment, the complaint pins 606 each act as both an electrical conduit between the terminals of the filter media 604 and the terminals of the connector (housing) 602, and a mechanical support for the assembly 600 as a whole. The manufacture of the connector housing 602 and filter media 604 of the embodiment of FIG. 10 are well understood in the electrical and materials arts, and accordingly will not be described further herein.

It will be recognized that while the embodiment of FIG. 10 illustrates a filtered media connector with capacitive media, other types of connectors and/or filter media may be used in conjunction with the invention. For example, one or more toroidal transformers or inductive reactors (“choke coils”) may be used as filter media (such as being disposed on and electrically connected to the terminals of the planar filter media 604 illustrated in FIG. 10). Alternatively, the connector 600 may be configured such that no filter media is employed. Furthermore, one or more compliant portions may be included anywhere along the length of the pins to provide a press-fit electrical connection with another external component such as a printed circuit board (PCB) of the type well known in the electrical arts, the component also being disposed in relative proximity to the housing 602. Other physical arrangements of the housing, filter media, and compliant pins may also be substituted with equal success. All such variations are considered to be within the scope of the invention disclosed herein.

In reference to FIGS. 11 through 16, the manufacturing process of the compliant pin 100 will now be described. The manufacturing process comprises two embodiments, one of which is referred to as the ‘strip’ method and the other is the ‘wire’ method. The ‘wire’ method embodiment of the manufacturing process comprises a two-step procedure whereby a length of metal wire is formed into a compliant pin. The first step involves “coining” a portion of the wire into what will become the compliant portion 107, followed by a “final-sizing” step.

Illustrated in FIG. 11 is a cross-sectional view of a coining system in an initial portion of the coining process. This process involves which involves a die 150, and a tool punch 152 for forming the cavity 112 into the wire 160. The die 150 is formed of conventional materials commonly used in dies for forming metal. Likewise, the tool punch 152 is made of conventional materials as used in the connector pin manufacturing industry such as tool steel. The wire 160 lies longitudinally inside a semi-circular groove 151 of the die 150, which in one embodiment has a diameter equal to or slightly larger than the width or diameter of the wire 160. It will be appreciated that the wire 160 may be circular, square, or rectangular in cross-section. The bottom of the tool punch 152 is approximately oval-shaped, and extends along the length and width desired for the cavity 112 of the compliant portion 107. As shown in FIG. 12, the process involves pressing the tool punch down, preferably in a single action, with enough force so as to displace the material of the wire so that it flows out toward the sides of the groove and upward so as to form the expanded or bulging outer surface 122 of the body portion 120 of the compliant portion 107 as shown in FIG. 6, as well as to form walls 166 about a portion of the tool punch 152, thereby creating the cavity 112. The walls 166 correspond to the deformable portion 108 described with reference to FIG. 6. It will be appreciated that the width of the tool punch 152, the diameter of the die groove 151, and the size and shape of the wire 160 may all be varied in relationship to each other to influence the final shape and size of the compliant portion 107 and its walls 166.

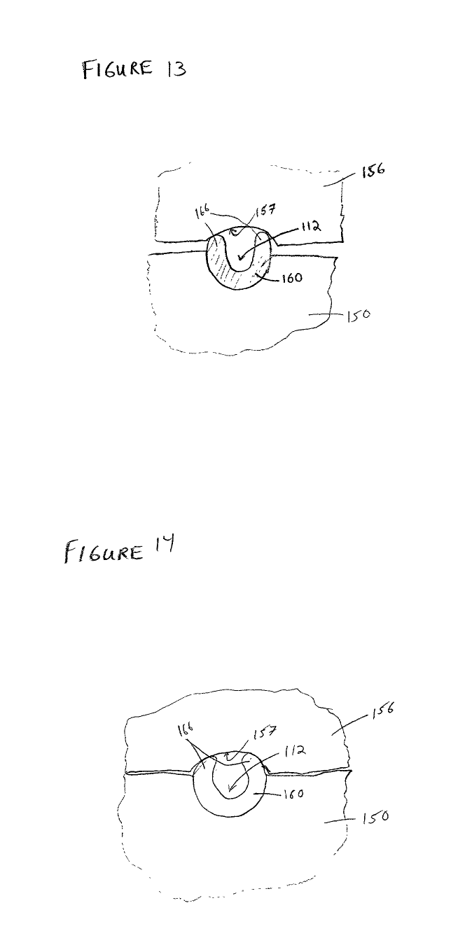

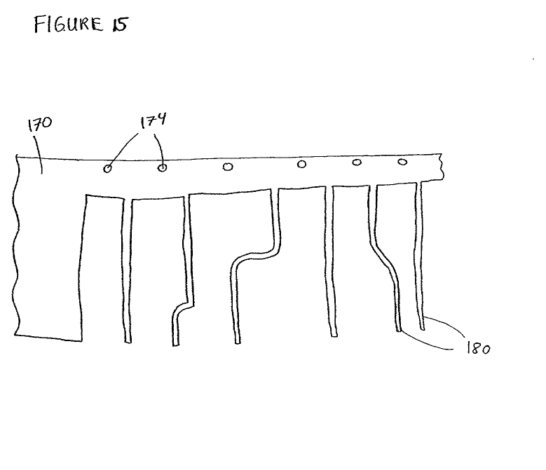

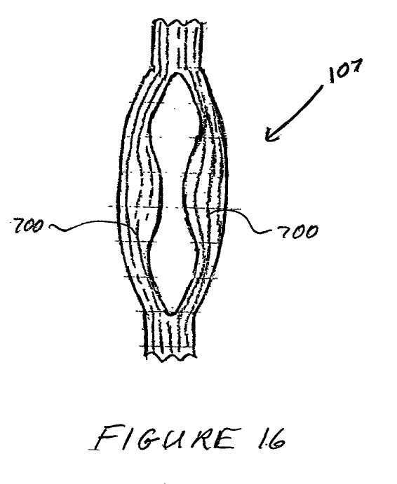

Illustrated in FIGS. 13 and 14 is a forming system undergoing a second step in the manufacturing procedure, referred to as the ‘final sizing’. As shown in FIG. 13, a second die 156 is brought down over the top of the first die, such that a groove 157 in the die 156 is aligned over the top of the wire 160. When the second die 156 is in contact with the walls 166, it is pressed down, preferably in a single action, with sufficient force to deform them slightly inwardly, by a desired amount. As seen in FIG. 14, this creates the desired roundness in the cavity 112 that is necessary for optimum effectiveness of the pin 100 as it is inserted into the aperture 504 within the PCB 501 or other component. In this configuration, the outward edges of the walls 166 extend over at least a portion of the cavity 112. Thus, upon insertion of the compliant portion 107 into an aperture of a device such as the PCB 501, the outward edges of the walls 166 will be compressed toward one another and extend further over the cavity 112. This arrangement provides for secure connection between the inner walls of the aperture and the compliant portion 107, including the walls 166 and enlarged body portion 120 of the compliant portion 107 (see FIG. 6).

The ‘strip’ method embodiment of the manufacturing process comprises a three-step procedure whereby a plurality of wires 180 are formed from a sheet of metal 170, to be subsequently formed into compliant pins 100. The sheet of metal includes a series of pilot holes 174 along its side, which are used simply for aligning the metal onto a track, which gets fed into a machine. The sheet then undergoes an automated process involving the three steps of blanking, which will be discussed in the following paragraph, followed by coining and final sizing, which were discussed above.

FIG. 15 shows a top view of the metal 170 after undergoing the first step in the process, which is referred to as blanking. This step involves cutting out (or blanking out) sections of the sheet such that the remaining portions define wires 180 of a desired length, width, and shape. This process is advantageous in one respect over the ‘wire’ manufacturing process because it allows the compliant pin to be shaped to specific configurations and sizes, such as having pre-formed bends. As illustrated in FIG. 15, it will be appreciated that the remaining wire portions 180 of the metal 170 are kept intact with the metal's perforated section, so as to allow for ease of handling. The remaining two steps of this manufacturing method are substantially identical to that of the ‘wire’ method, whereby the wires 180 are subjected to the process steps of coining and final sizing. Other machining processes such as tapering the ends of the compliant pin are optional, but can certainly be automated and incorporated into this procedure as well.

It should be noted, that while the two embodiments both produce a compliant pin of sufficient shape and functionality, there are tradeoffs between using one method of manufacture over the other. As mentioned above, the strip method is advantageous in respect to the fact that it allows the option of choosing specific shapes and configurations to what the final compliant pin will look like. For example, if an application required a compliant pin having two bends and a curved portion in a specific orientation to the compliant portion, the sheet of metal 170 could simply be cut that way so that the bends and/or curves wouldn't have to be formed at a later time. If the same configuration was required of a pin manufactured from the wire method, it would require additional steps to be performed separately.

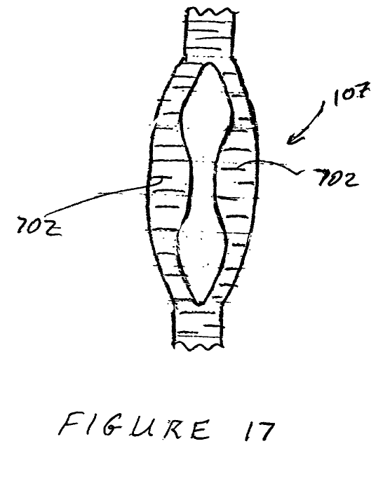

However, a disadvantage in using the strip method over the wire method is based on the direction in which the grain of the metal travels. As shown in FIG. 16, the grain 700 of a compliant pin manufactured from the ‘wire’ method runs longitudinally along the pin, due to the process by which the wire is extruded. In the sheet of metal 170 utilized in the strip method by comparison, FIG. 17 shows that the grain 702 runs parallel to the longitudinal direction of the metal sheet of FIG. 15 due to the way that the sheet is rolled, resulting in transverse grain lines 702. This difference in directionality of grain lines equates to slightly more strength and durability of the compliant pins formed from the ‘wire’ method, however insignificant the difference may be. Yet a further advantage to the ‘wire’ method is that it requires only the two manufacturing steps described above as opposed to three.

An advantage which is common to both methods, in comparison to the prior art, is that the above described methods of manufacture produce a compliant pin which is without seams between its compliant portion and its body, which could weaken the structural and/or electrical integrity of the pin. By the method of coining the wire to produce the cavity, as opposed to processes such as folding used in other connector pins, the material is able to maintain its internal molecular configuration for optimum external strength.

In view of the above, one will appreciate that the invention overcomes the longstanding problem in the industry of maintaining retention of connector pins, by providing a compliant pin which: (1) maintains a solid grip between a compliant portion and an aperture; (2) does so, without causing cracking or warpage to either upon insertion, and; (3) does so while maintaining a “memory” so as to prevent degradation of the connection over time. Furthermore, the invention overcomes the problems encountered in efforts to manufacture a pin having features such as those set forth above by providing a manufacturing process requiring a minimum number of process steps to produce the desired pin.

While the invention disclosed herein has been described by means of specific embodiments and applications thereof, numerous modifications and variations could be made thereto by those skilled in the art without departing from the scope of the invention as set forth in the claims.

What is claimed is:

1. A compliant pin, comprising:
a substantially longitudinal body element having first and second ends; and,
at least one compliant portion located along said longitudinal body, said compliant portion having first and second distal elements, said first and second distal elements being seamlessly connected to the body and defining walls of a cavity within said body and being configured so as to be deformed inwardly toward the cavity in response to contact with walls defining an aperture as said compliant portion is inserted into said aperture.

2. The compliant pin of claim 1, having only one compliant portion.

3. The compliant pin of claim 2, wherein said compliant portion is disposed in proximity to at least one of said first and second ends.

4. The compliant pin of claim 1, wherein the distal elements extend outward substantially radially from the longitudinal axis of the body a distance greater than the sides of said body.

5. The compliant pin of claim 1, wherein the lateral cross-section of said compliant portion is substantially oval in configuration, with forward ends of its sides directed at least partially inwardly over the cavity.

6. The compliant pin of claim 1, wherein at least one of the first and second ends is tapered to facilitate insertion of the pin into an aperture.

7. The compliant pin of claim 1, wherein at least a portion of the compliant portion, other than the distal elements, defines an outer surface which is located a distance further from the longitudinal axis of the body than is the surface of the sides of said body.

8. A complaint pin configured to be inserted into a press fit hole of a connector housing, comprising:
a longitudinal body having first and second ends; and,
a retainer portion, located on the longitudinal body between the first and second ends, wherein the retainer portion includes at least one distal element which is seamlessly connected to the body and which extends outwardly from the longitudinal body, and at least one cavity in the longitudinal body adjacent to said at least one distal element such that said at least one distal element deforms inwardly at least partially toward said at least one cavity when said retainer portion is inserted into the press fit hole of the connector housing.

9. A compliant pin as defined in claim 8, wherein the at least one distal element comprises two distal elements which extend outwardly from the longitudinal body on substantially opposite sides of the at least one cavity.

10. The compliant pin as defined in claim 9, wherein outward ends of the distal elements extend at least partially over the at least one cavity.

11. A method of manufacturing a compliant pin comprising:
providing a pin body;
coining the pin body in at least one location so as to define a cavity having at least one wall seamlessly connected to said pin body; and
forming the at least one wall into a desired shape and configuration.

12. The method of claim 11, wherein the act of providing a pin body comprises providing a wire pin.

13. The method of claim 11, wherein the act of providing a pin body comprises blanking at least a portion of a metal sheet to define at least one wire pin.

14. The method of claim 11, wherein the act of coining the pin body comprises:
placing the at least one location of the pin body into a groove of a die; and
applying pressure from a tool punch onto the at least one location of the pin body so as to displace a portion of said pin body about a portion of said tool punch to thereby define the at least one wall adjacent the cavity in said pin body.

15. The method of claim 14, wherein the act of applying pressure defines at least two walls, each adjacent a different portion of the cavity in the pin body.

16. The method of claim 14, wherein the act of applying pressure additionally displaces a portion of the pin body such that the diameter of the pin body is increased in at least a portion of the at least one location with respect to the diameter of said pin body prior to the act of applying pressure.

17. The method of claim 14, wherein the diameter of the groove of the die is larger than the diameter of the pin body and wherein the width of the tool punch is selected with respect to the diameter of said pin body and the diameter of said groove such that when pressure is applied from said tool punch onto the at least one location of said pin body within said groove, a portion of said pin body is displaced about a portion of said tool punch to thereby define the at least one wall adjacent the cavity in said pin body.

18. The method of claim 14, wherein the act of applying pressure comprises applying pressure from a tool punch onto the at least one location of the pin body in a single punch action.

19. The method of claim 11, wherein the act of forming the at least one wall comprises applying force onto the at least one wall so as to move a forward edge thereof at least partially over the cavity.

20. The method of claim 19, wherein the act of forming comprises applying force onto the at least one wall in a single forming action.

21. The method of claim 19, wherein the at least one wall comprises at least two walls, each adjacent a different portion of the cavity in the pin body.

22. The method of claim 21, wherein the act of forming the at least one wall comprises applying force onto each of the at least two walls so as to move a forward edge on each of said at least two walls at least partially over the cavity.

23. The method of claim 11, wherein the act of forming the at least one wall comprises:
contacting a portion of the at least one wall with a forming die; and
transmitting force from the forming die onto the at least one wall so as to move at least an edge of the at least one wall to a position over the cavity.

24. A method of manufacturing a plurality of compliant pins having at least one compliant portion which includes a cavity, comprising:
blanking a plurality of sections on a sheet of metal to define wires of a desired length, width, and shape;
coining each of the wires in at least one location such that a cavity having at least one wall is created on each wire with a seamless connection between said at least one wall and the associated wire; and
forming the at least one wall on each wire into a desired shape and configuration.

25. The method of claim 24, wherein the act of coining each of the wires comprises:
placing the at least one location of a wire into a groove of a die; and
applying pressure from a tool punch onto the at least one location of the wire so as to displace a portion of said wire about a portion of said tool punch to thereby define the at least one wall adjacent the cavity in said wire.

26. The method of claim 25, wherein the act of applying pressure defines at least two walls, each adjacent a different portion of the cavity in the wire.

27. The method of claim 25, wherein the act of applying pressure additionally displaces a portion of the wire such that the diameter of the wire is increased in at least a portion of the at least one location with respect to the diameter of said wire prior to the act of applying pressure.

28. The method of claim 24, wherein the act of forming the at least one wall comprises applying force onto the at least one wall so as to move a forward edge thereof at least partially over the cavity.

29. An apparatus for manufacturing a compliant portion of a compliant pin comprising:
a pin body;
means for coining the pin body in at least one location so as to define a cavity having at least one wall seamlessly connected to said pin body; and
means for forming the at least one wall into a desired shape and configuration.

30. A system for manufacturing a compliant portion of a compliant pin comprising:
a first die having a first groove formed therein for receiving a pin body;
a punch tool which is configured with respect to said first die and said pin body such that upon pressing said punch tool against a portion of said pin body which is lying in said first groove of said first die, said pin body will deform such that said portion of said pin body being contacted by said punch tool will flow outwardly and upwardly against at least one surface of said first groove so as to create walls and a cavity in said pin body, said walls at least partially enclosing said cavity within said portion of said pin body; and
a second die having a second groove formed therein and configured with respect to said first die and said pin body such that when said second die is pressed against said walls it deforms said walls slightly inwardly such that at least a portion of each of said walls is located above said cavity.
